(19) United States
(12) Patent Application Publication
(10) Pub. No.: US 2010/0127392 A1
(43) Pub. Date: May 27, 2010

(54) Semiconductor die

(75) Inventors: Joe Yang, Taichung City (TW); Su-Hon Lin, Keelung City (TW)

Correspondence Address: CHARLES E. BAXLEY, ESQUIRE, 90 JOHN STREET, SUITE 309, NEW YORK, NY, 10038, US

(73) Assignee: Joe YANG

(21) Appl. No.: 12/315,095

(22) Filed: Nov. 25, 2008

(51) Int. Cl. H01L 23/48

(52) U.S. Cl. 257/737; 257/E23.01

(57) ABSTRACT

A semiconductor die includes a semiconductor substrate, electrodes provided on the semiconductor substrate, an isolating layer provided on the electrodes, an upper protective layer provided on the electrodes and the isolating layer, pads provided on the upper protective layer and connectors inserted through the upper protective layer and used to connect the electrodes to the pads. The area of the pads is larger than that of the electrodes.

### FIELD OF INVENTION

The present invention relates to a semiconductor die and, more particularly, to a semiconductor die that is made without having to involve a packaging process and can directly be connected to a printed circuit board (“PCB”) or a package substrate.

### BACKGROUND OF INVENTION

An active semiconductor device may be a diode, an integrated circuit, a transistor (MOS, FET or IGBT), a high-power semiconductor device, a photoactive element or a photocell of gallium arsenide. An active semiconductor device is generally made in a preparatory process, an front-end process and a back-end process. In the preparatory process, a semiconductor substrate is made from silicon or gallium. In the front-end process, a semiconductor die is made on the semiconductor die. In the back-end process, a semiconductor device is made by packaging the semiconductor die.

Referring to FIG. 2, in the preparatory step, the semiconductor substrate 3 is made of a material selected from the IV elements such as silicon and gallium or the III-V compounds such as gallium arsenide and gallium phosphide.

In the front-end process, the semiconductor substrate 3 is subjected to repeated photolithography, etching and impurity-dosing. By a thermal diffusion method, an ion-injection method or an epitaxial growth method, an epitaxial growth layer 31 and an isolating layer 32 such as an oxide film are formed on the semiconductor substrate 3. By vapor deposition, aluminum, copper, titanium, chromium, platinum, gold or alloy is provided on the semiconductor die to form electrodes 51 including electrodes 51 include a gate, a collector and a source and wiring. Thus, a semiconductor die 5 is made.

Referring to FIG. 1, there are shown four conventional manufacturing processes that can be used as the back-end process for making the semiconductor device by packaging the semiconductor die 5.

In a quad flat package (“QFP”), a semiconductor die 50 is formed with electrodes 51. A wire frame 60 is formed with pins 61. The semiconductor die 50 is located on the wire frame 60. By bonding, wires 62 are provided for connecting the electrodes 51 of the semiconductor die 50 to the pins 61 of the wire frame 60. By plastic packaging, the semiconductor die 50 and the wires 62 are packaged in a package 65. Then, the pins 61 of the wire frame 60 are connected to a printed circuit 91 of a substrate 90. This conventional manufacturing process is complicated and requires special and expensive equipment such as a soldering machine and a plastic packaging machine. Moreover, the heat dissipation of the semiconductor die 50 is poor so that the performance of the semiconductor die 50 is unstable.

In a solder ball grid array (“BGA”), a semiconductor die 50 is formed with electrodes 51. The semiconductor die 50 is located on a wire board 70. By bonding, wires 71 are provided for connecting the electrodes 51 of the semiconductor die 50 to contacts of the wire board 70. By plastic packaging, the semiconductor die 50 and the wires 71 are packaged in a package 75. By solder ball-implanting, solder balls 72 are formed beneath the wire board 70. By soldering, the solder balls 72 of the wire board 70 are connected to a printed circuit 91 of a substrate 90. This conventional manufacturing process is complicated and requires special and expensive equipment such as a soldering machine, a solder ball-implanting machine and a plastic packaging machine. Moreover, the heat dissipation of the semiconductor die 50 is poor so that the performance of the semiconductor die 50 is unstable.

In a flip semiconductor die (“FC”), a semiconductor die 50 is formed with electrodes 51. Then, in a semiconductor-manufacturing process, bumps 55 are formed on the electrodes 51 of the semiconductor die 50. The bumps 55 may be tin or gold solder balls. The bumps 55 are attached to a wire board 80. By solder ball-implanting, solder balls 82 are formed beneath the wire board 80. By plastic injection, the semiconductor die 50 and the bumps 55 are packaged in a package 85. By soldering, the solder balls 82 of the wire board 80 are connected to a printed circuit 91 of a substrate 90. This conventional manufacturing process is complicated and requires special and expensive equipment such as a solder ball-implanting machine and a plastic packaging machine. Moreover, the heat dissipation of the semiconductor die 50 is poor so that the performance of the semiconductor die 50 is unstable.

In a semiconductor wafer level semiconductor die scale package (“WLCSP”), a semiconductor die 50 is formed with electrodes 51. In a semiconductor-manufacturing process, bumps 55 are formed on the electrodes 51 of the semiconductor die 50. The bumps 55 may be tin or gold solder balls. The bumps 55 are connected to a printed circuit 91 of a substrate 90. The heat dissipation of the semiconductor die 50 is good. However, the diameter or height of the bumps 55 is often inadequate so that the yield is low.

The present invention is therefore intended to obviate or at least alleviate the problems encountered in prior art.

### SUMMARY OF INVENTION

It is an objective of the present invention to provide an inexpensive semiconductor die.

It is another objective of the present invention to provide a semiconductor die with excellent heat radiation.

It is another objective of the present invention to provide a semiconductor die for use at a low cost.

To achieve the foregoing objectives, the semiconductor die includes a semiconductor substrate, electrodes provided on the semiconductor substrate, an isolating layer provided on the electrodes, an upper protective layer provided on the electrodes and the isolating layer, pads provided on the upper protective layer and connectors inserted through the upper protective layer and used to connect the electrodes to the pads. The area of the pads is larger than that of the electrodes.

Other objectives, advantages and features of the present invention will become apparent from the following description referring to the attached drawings.

### BRIEF DESCRIPTION OF DRAWINGS

The present invention will be described via the detailed illustration of embodiments versus the prior art referring to the drawings.

FIG. 1 is a table of four conventional processes for manufacturing a semiconductor device by packaging a semiconductor die versus a manufacturing process according to a first embodiment of the present invention.

FIG. 2 is a cross-sectional view of the semiconductor die packaged in any of the conventional manufacturing processes shown in FIG. 1.

FIG. 3 is a cross-sectional view of a semiconductor wafer used in the manufacturing process according to the first embodiment of the present invention.

FIG. 4 is a cross-sectional view of a semiconductor die cut from the semiconductor wafer shown in FIG. 3.

FIG. 5 is a top view of the semiconductor die shown in FIG. 4.

FIG. 6 is a top view of a semiconductor die according to a second embodiment of the present invention.

FIG. 7 is a cross-sectional view of the semiconductor die of FIG. 6.

FIG. 8 is a cross-sectional view of the semiconductor die of FIG. 4 inverted and mounted on a printed circuit board.

FIG. 9 is a cross-sectional view of the semiconductor die of FIG. 4 inverted and mounted on a package substrate, in turn, mounted on a printed circuit board.

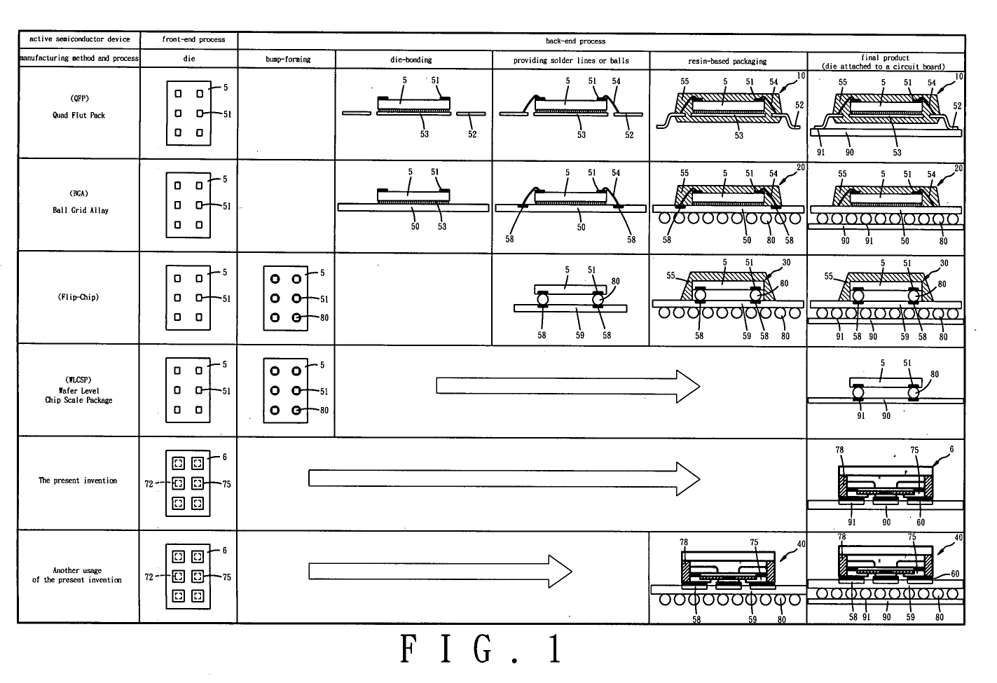

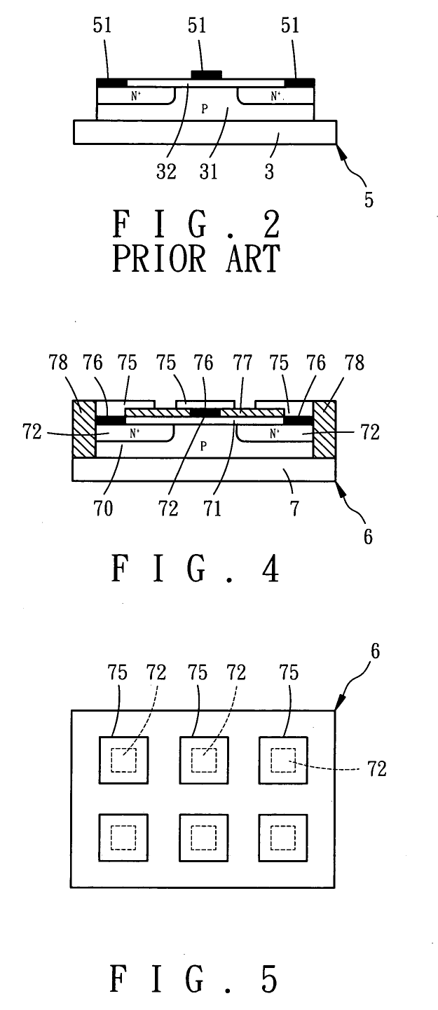

### DETAILED DESCRIPTION OF PREFERRED EMBODIMENT

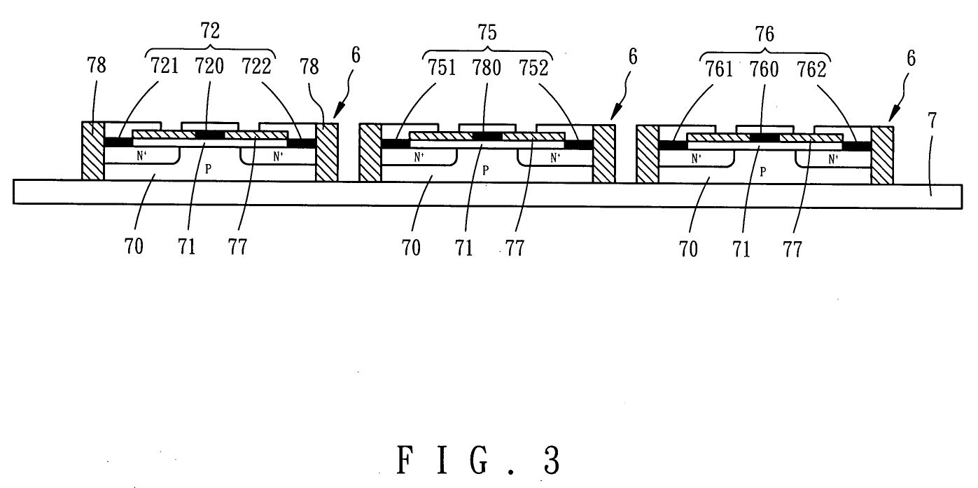

Referring to FIGS. 3 through 5, according to a first embodiment of the present invention, a semiconductor substrate 7 is made of a material selected from the IV elements such as silicon and gallium or the III-V compounds such as gallium arsenide and gallium phosphide. The semiconductor substrate 7 is subjected to repeated photolithography, etching and impurity-dosing. By a thermal diffusion method, an ion-injection method or an epitaxial growth method, an epiaxial growth layer 70 and an isolating layer 71 such as an oxide film are formed on the substrate 7. An electrode array 72 and wiring are formed on the substrate 7 by vapor deposition. The electrode array 72 includes at least one gate 720, at least one collector 721 and at least one source 722. Thus, a semiconductor die 6 is made.

An upper protective layer 77 is provided on the isolating layer 71 and the electrodes 72. A peripheral protective layer 78 is provided around the semiconductor substrate 6. The upper protective layer 77 and the peripheral protective layer 78 are made of an isolating, water-proof and thermally conductive material to protect the semiconductor substrate 6 from vapor, oxidation and short-circuiting and facilitate the heat radiation of the semiconductor substrate 6. Therefore, there is no need for a package that often entails a high cost and a low yield.

A pad array 75 is provided on the upper protective layer 77 during a semiconductor-manufacturing process such as epitaxial growth, etching or vapor deposition. The pad array 75 includes at least one pad 750, at least one pad 751 and at least one pad 752. The pads 750, 751 and 752 are made of gold, silver, copper, aluminum, tin, chromium, palladium, platinum, molybdenum and an alloy. The area of the pads 750, 751 and 752 is larger than that of the gate 720, the collector 721 and the source 722.

A connector unit 76 is inserted through the upper protective layer 77. The connector unit 76 includes connectors 760, 761 and 762. The connector 760 is used to connect the pad 750 to the gate 720. The connector 761 is used to connect the pad 751 to the collector 721. The connector 762 is used to connect the pad 752 to the gate 722.

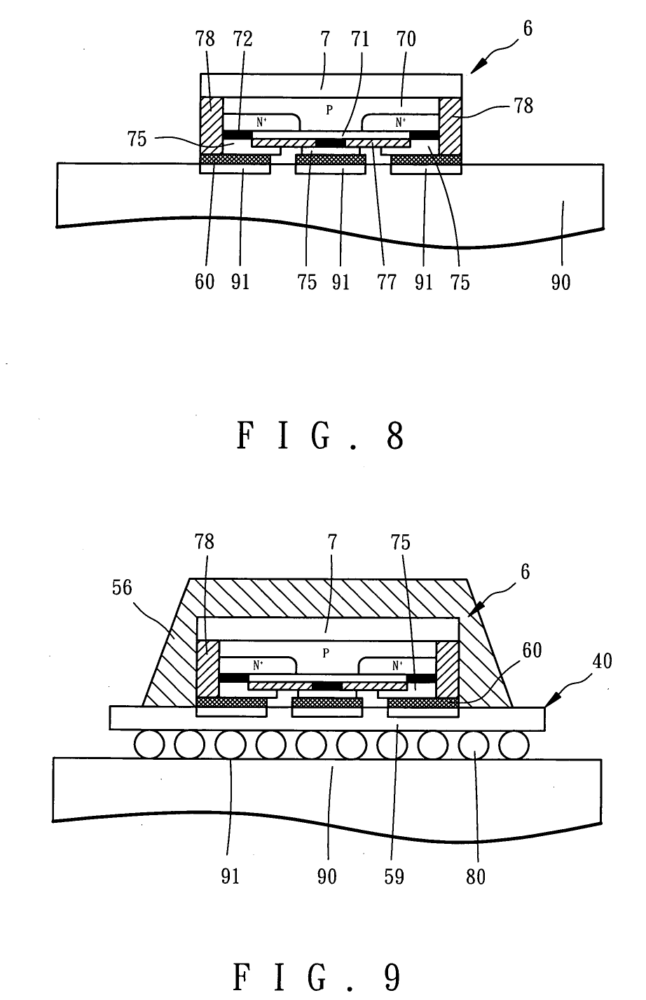

Referring to FIG. 8, the semiconductor die 6 is inverted and located above a printed circuit board 90. The pad array 75 is connected to a printed circuit 91 of the printed circuit board 90 based on the surface mounted technology.

Referring to FIG. 9, the semiconductor die 6 is inverted and located above a semiconductor substrate 59. The pad array 75 is connected to a printed circuit of the semiconductor substrate 59 by the surface mounted technology. A package 56 is used to pack the semiconductor die 6 by plastic injection, thus forming a semiconductor device 40. Then, the semiconductor device 40 may be connected to the printed circuit 91 of the printed circuit board 90 through solder balls 80.

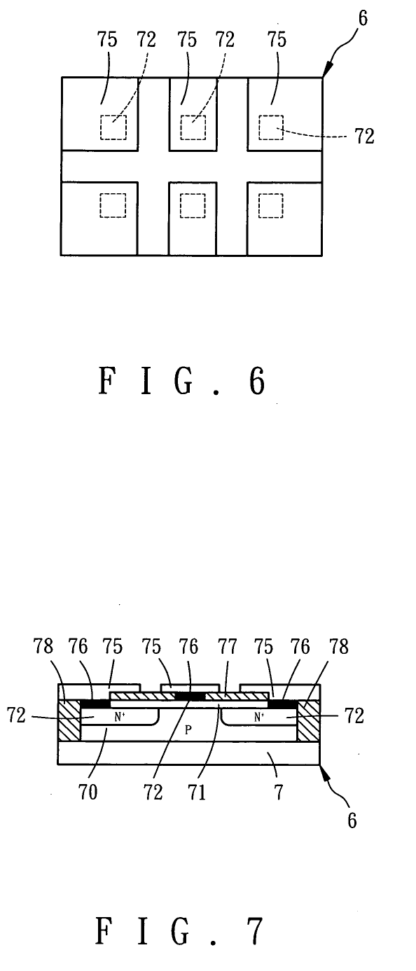

Referring to FIGS. 6 and 7, there is shown a semiconductor die 6 according to a second embodiment of the present invention. The second embedment is like the first embodiment except including larger pads 750, 751 and 752. The pads 750, 751 and 752 extend to the periphery of the semiconductor die 6. The area of the pads 750, 751 and 752 and the distance between the pads 750, 751 and 752 are determined based on the area of the semiconductor die 6 and electric bridging tolerance.

In several aspects, the semiconductor die according to the present invention is advantageous over the conventional semiconductor die discussed in the BACKGROUND OF INVENTION. At first, the semiconductor die 6 is inexpensive compared with the prior art because it is protected without the need for a package. The isolating layer 71 and the electrodes 72 are protected with the upper protective layer 77, and the periphery of the semiconductor die 6 is protected with the peripheral protective layer 78. The protective layers 77 and 78 are made of an isolating, water-proof and thermally conductive material to protect the semiconductor substrate 6 from vapor, oxidation and short-circuiting and facilitate the heat radiation of the semiconductor substrate 6.

Secondly, the heat radiation of the semiconductor die 6 is better than that of the prior art. The semiconductor die 6 is not packaged in a package so that heat can effectively be radiated from the semiconductor die 6 without being hindered by a package.

Thirdly, the cost in the use of the semiconductor 6 is inexpensive compared with that of the prior art. The pads 75 are large so that they can directly be connected to the printed circuit board 90 or the package substrate 59 based on the surface mounted technology. There is no need for pins or solder balls.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. A semiconductor die comprising:
a semiconductor substrate;
electrodes provided on the semiconductor substrate;
an isolating layer provided on the electrodes;
an upper protective layer provided on the electrodes and the isolating layer;
pads provided on the upper protective layer, wherein the area of the pads is larger than that of the electrodes; and
connectors inserted through the upper protective layer and used to connect the electrodes to the pads.

2. The semiconductor die according to claim 1, wherein the upper protective layer is made of an isolating, water-proof and thermally conductive material to protect the semiconductor substrate from vapor, oxidation and short-circuiting and facilitate the heat radiation of the semiconductor substrate.

3. The semiconductor die according to claim 1, wherein the electrodes comprises at least one gate, collector and source.

4. The semiconductor die according to claim 1, wherein the area of the pads and the distance between the pads are determined based on the entire area of the semiconductor die and an electric bridging tolerance.

5. The semiconductor die according to claim 1 comprising a peripheral protective layer provided around the semiconductor die.

6. The semiconductor die according to claim 1, wherein the pads are made of a material selected from a group consisting of gold, silver, copper, aluminum, tin, chromium, palladium, platinum, molybdenum and an alloy.
